(19) United States
(12) Patent Application Publication
(10) Pub. No.: US 2007/0275157 A1
(43) Pub. Date: Nov. 29, 2007

(54) Apparatus and method for measuring widthwise ejection uniformity of slit nozzle

(75) Inventor: Kang II Cho, Yongin-si (KR)

Correspondence Address: STEPTOE & JOHNSON LLP, 1330 CONNECTICUT AVENUE, N.W., WASHINGTON, DC, 20036, US

(73) Assignee: K.C. TECH CO., LTD., Ansong-Shi (KR)

(21) Appl. No.: 11/798,867

(22) Filed: May 17, 2007

(30) Foreign Application Priority Data
May 23, 2006 (KR) 10-2006-0046137

(51) Int. Cl. C23C 16/52; B05C 11/00

(52) U.S. Cl. 427/8; 118/667; 118/692

(57) ABSTRACT

An apparatus for measuring withwise ejection uniformity of a slit nozzle comprises a plurality of oil pressure measuring units that are arranged in parallel in a widthwise direction of the slit nozzle so as to measure ejection pressure of fluid to be ejected from an ejection port of the slit nozzle, each oil pressure measuring unit having an oil-pressure detection surface facing the ejection port of the slit nozzle; and a control unit that measures ejection pressure applied to the oil pressure measuring unit so as to calculate the uniformity to display.

### CLAIM OF PRIORITY

This application claims priority under 35 USC 119 to to Korean Patent Application No. 10-2006-0046137, filed on May 23, 2006, which is incorporated by reference in its entirety.

### BACKGROUND OF THE INVENTION

1. Field of the Invention

The present invention relates to an apparatus and method for measuring widthwise ejection uniformity of photoresist to be ejected from a slit nozzle of a substrate coating apparatus, and more specifically, to an apparatus and method for measuring widthwise ejection uniformity of photoresist to be ejected along a widthwise direction of a slit nozzle when the photoresist is ejected from the slit nozzle of a substrate coating apparatus.

2. Description of the Related Art

In general, when a liquid crystal display element is manufactured, a process error usually occurs in a photo process using photoresist. When the photoresist is not uniformly coated, a difference in resolution and linewidth occurs in the subsequent process. Further, a difference in refractive index occurs, thereby generating such a defect that the difference is displayed as it is.

Recently, there is a demand for reducing a process time required for coating photoresist on a substrate. Therefore, researches for a method, in which the photoresist is uniformly coated within a short time and is dried, need to be carried out.

As for a method of coating photoresist on a substrate, there are provided a roll coating method, a spin coating method, and a slit coating method. In the roll coating method, photoresist is loaded on a round roll, and the roll is rolled on a substrate in a predetermined direction such that the photoresist is coated. In the spin coating method, a substrate is placed on a disk-shaped support, and photoresist is dropped in the center of the substrate. Then, the substrate is rotated so that the photoresist is coated on the substrate by the centrifugal force. In the slit coating method, while photoresist is ejected onto a substrate through a slit-shaped nozzle, scanning is performed in a predetermined direction such that the photoresist is coated.

In the roll coating method among the above-described methods, it is difficult to precisely adjust the uniformity of photoresist film and the film thickness thereof. Therefore, in order to form a pattern with high precision, the spin coating method is used. However, the spin coating method is suitable for coating photosensitive materials on a small-sized substrate such as a wafer, but is not suitable for a substrate for flat panel display, such as a glass substrate for liquid crystal display panel, which is large-sized and heavy. That is because, as a substrate is large-sized and heavy, there are difficulties in rotating the substrate at high speed. Further, when the substrate is rotated at high speed, the substrate can be broken, or a large amount of energy is consumed. In this reason, the slit coating method is usually used for coating photoresist on a large-sized glass substrate.

FIG. 1 is a perspective view of a general slit coater. FIG. 2 is a sectional view showing a state where photoresist is coated on a substrate by the slit coater shown in FIG. 1.

Referring to FIG. 1, the slit coater 100 includes a slit nozzle 110 which coats photoresist PR on a substrate GS, a pair of nozzle transfer units 120 which transfer the slit nozzle in a predetermined direction, a photoresist supply section 115 which is attached on one of the nozzle transfer units, a first photoresist supply line 116 which delivers photoresist PR from the photoresist supply section 115 to the slit nozzle 110, and a second photoresist supply line 117 which supplies photoresist PR to the photoresist supply section 115.

The slit nozzle 110 is formed in a long bar shape. The slit nozzle 110 has an ejection port 112 formed in the center of the lower end thereof facing the substrate GS, the ejection port 112 being formed in a minute slit shape. Through the ejection port 112, a predetermined amount of photoresist PR is ejected onto the substrate GS. The photoresist supply section 115 serves to supply photoresist PR to the slit nozzle 110 and to apply a constant pressure to the photoresist PR such that the photoresist PR is ejected. Typically, the photoresist supply section 115 including a pump applies a constant pressure to the slit nozzle 110 such that the photoresist PR stored in the slit nozzle 110 is ejected onto the substrate GS by the pressure.

Referring to FIG. 2, the slit nozzle 110 of the slit coater constructed in such a manner ejects photoresist PR onto the substrate GS, while vertically advancing at predetermined speed from one end of the substrate GS. Then, the photoresist PR is uniformly coated on the substrate GS.

At this time, the slit nozzle 110 of the slit coater 100 should uniformly eject photoresist PR in a widthwise direction of the slit nozzle 110 as well as in the transfer direction of the slit nozzle 110. In order to uniformly eject photoresist PR in the transfer direction of the slit nozzle 110, a change in pressure to be applied to the photoresist PR by the photoresist supply section 115 in accordance with a time, transfer speed of the slit nozzle 110, and a distance between the substrate GS and the slit nozzle, and the like should be controlled.

On the other hand, in order to uniformly eject photoresist PR in the widthwise direction of the slit nozzle 110, the space of the ejection port according to the widthwise direction of the slit nozzle 110 should be adjusted. For this, the slit nozzle has a plurality of bolts (not shown) for adjusting the space of the ejection port, the plurality of bolts being provided to be spaced at a predetermined distance along the widthwise direction of the slit nozzle. In order to uniformly eject photoresist PR in the widthwise direction of the slit nozzle 110, the thickness distribution of photoresist PR to be ejected by the slit nozzle 110, that is, the uniformity of photoresist PR is measured with respect to the widthwise direction of the slit nozzle 100. Then, the space of the ejection port of the slit nozzle 110 is adjusted using the measured uniformity of the photoresist PR.

As such, in order to uniformly eject photoresist PR in the widthwise direction of the slit nozzle 110, the measuring of the widthwise uniformity of the slit nozzle 110 is performed a plurality of times, so that reliability of uniformity data is secured. Then, the space of the ejection port of the slit nozzle is adjusted. After that, measurement for confirming the uniformity of photoresist PR through the adjusted ejection port should be again performed a plurality of times.

Conventionally, after photoresist PR is directly coated on the substrate by a slit coater, the thickness of the coated photoresist PR is directly measured. In such a method, however, since the photoresist PR is directly coated on the substrate, the expensive substrate and photoresist PR are wasted. Further, as a substrate increases in size, an amount of consumed photoresist further increases.

Further, when the thickness of the photoresist PR coated on a substrate is measured, it is not easy to measure the thickness of the photoresist PR in a state where the photoresist PR is not dried. Therefore, after the coated photoresist PR is subjected to a drying process, the thickness thereof should be measured, which means that it is very inconvenient to measure the thickness of the coated photoresist PR. Furthermore, since the thickness of the photoresist is measured after the coated photoresist is subjected to a drying process, the thickness of the photoresist PR which is actually coated cannot be directly measured. Therefore, it is impossible to directly measure ejection uniformity of photoresist. In addition, since the thickness of the photoresist PR coated on the substrate is very small, an expensive thickness measuring equipment is needed, in order to measure the thickness.

### SUMMARY OF THE INVENTION

An advantage of the present invention is that it provides an apparatus and method for measuring ejection uniformity of a slit nozzle, which can simply and precisely measure widthwise ejection uniformity of photoresist to be ejected onto a substrate by the slit nozzle

Additional aspect and advantages of the present general inventive concept will be set forth in part in the description which follows and, in part, will be obvious from the description, or may be learned by practice of the general inventive concept.

According to an aspect of the invention, an apparatus for measuring withwise ejection uniformity of a slit nozzle comprises a plurality of oil pressure measuring units that are arranged in parallel in a widthwise direction of the slit nozzle so as to measure ejection pressure of fluid to be ejected from an ejection port of the slit nozzle, each oil pressure measuring unit having an oil-pressure detection surface facing the ejection port of the slit nozzle; and a control unit that measures ejection pressure applied to the oil pressure measuring unit so as to calculate the uniformity to display.

According to another aspect of the invention, an apparatus for measuring withwise ejection uniformity of a slit nozzle comprises an oil pressure measuring unit that is disposed in a widthwise direction of the slit nozzle so as to measure ejection pressure of fluid to be ejected from an ejection port of the slit nozzle, the oil pressure measuring unit having an oil-pressure detection surface facing the ejection port of the slit nozzle; a control unit that measures ejection pressure applied to the oil pressure measuring unit so as to calculate the uniformity to display; and a transfer unit that transfers the oil pressure measuring unit in the widthwise direction of the slit nozzle.

Preferably, the slit nozzle ejects water or gas.

Preferably, the oil pressure measuring unit is surface-treated so as to have hydrophobicity with respect to ejected fluid.

Preferably, the oil pressure measuring unit has an inclined surface formed between the detection surface and the front and rear surfaces thereof. The corner between the detection surface and the inclined surface is formed in a round shape.

Preferably, the oil pressure measuring unit includes a piezoelectric element.

According to a further aspect of the invention, a method for measuring widthwise ejection uniformity of a slit nozzle comprises ejecting fluid through an ejection port of the slit nozzle; and measuring ejection pressure of the fluid to be ejected in the widthwise direction of the slit nozzle.

Preferably, the measuring of the ejection pressure of the fluid includes arranging a plurality of oil pressure measuring units in the widthwise direction of the slit nozzle so as to measure the ejection pressure at the same time. Alternately, the measuring of the ejection pressure of the fluid includes measuring the ejection pressure while transferring one oil pressure measuring unit in the widthwise direction of the slit nozzle.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view of a general slit coater;

FIG. 2 is a sectional view showing a state where photoresist is coated on a substrate by the slit coater shown in FIG. 1;

FIG. 3 is a schematic front view of a slit nozzle and an apparatus for measuring widthwise ejection uniformity of the slit nozzle according to an embodiment of the invention;

FIG. 4 is a side view for explaining a state where a fluid is ejected by the apparatus for measuring widthwise ejection uniformity of slit nozzle according to the invention; and

FIG. 5 is a front view of a slit nozzle and an apparatus for measuring widthwise ejection uniformity of the slit nozzle according to another embodiment of the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an apparatus and method for measuring widthwise ejection uniformity of slit nozzle according to the present invention will be described in detail with reference to the accompanying drawings. The apparatus for measuring ejection uniformity according to the invention serves to measure ejection uniformity of photoresist to be ejected by the slit nozzle of the slit coater described in the related art. The descriptions of the slit coater will be omitted.

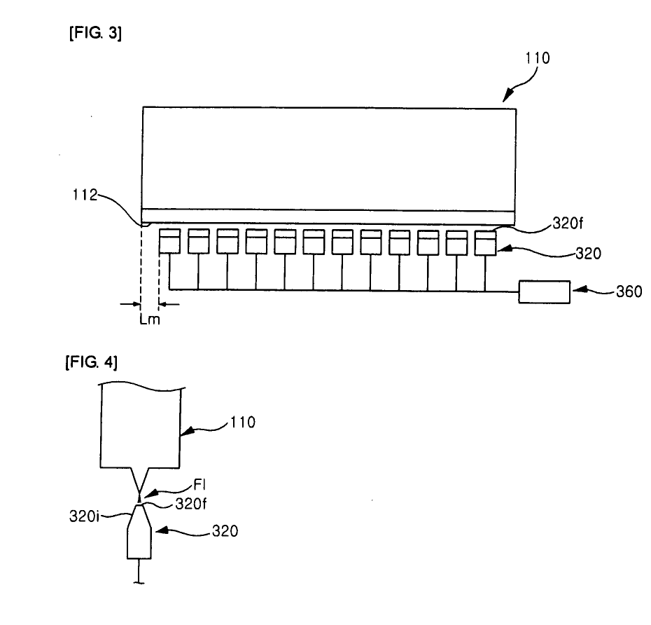

FIG. 3 is a schematic front view of a slit nozzle and an apparatus for measuring widthwise ejection uniformity of the slit nozzle according to the invention. FIG. 4 is a side view for explaining a state where a fluid is ejected by the apparatus for measuring widthwise ejection uniformity of slit nozzle according to the invention.

Referring to FIG. 3, the apparatus for measuring widthwise ejection uniformity of slit nozzle according to the invention serves to measure ejection pressure of fluid, which is ejected from the slit nozzle, along a widthwise direction of the slit nozzle.

That is, the apparatus for measuring widthwise ejection uniformity of slit nozzle according to the invention includes a plurality of oil pressure measuring units 320 which are fixed and disposed under an ejection port 112 as the lower end of the slit nozzle 110 so as to be spaced at a predetermined distance from the ejection port 112; and a control unit 360 which is connected to each of the oil pressure measuring units 320. The control unit 360 receives a signal from each of the oil pressure measuring units 320 so as to measure ejection pressure applied to the oil pressure measuring unit 320 and then calculates the uniformity of ejected fluid Fl to display.

The plurality of oil pressure measuring units 320 are arranged in line so as to be spaced at a predetermined distance along the widthwise direction of the slit nozzle 110. Each of the oil pressure measuring units 320 has an oil detection surface 320f disposed to face the ejection port 112 of the slit nozzle 110. As the number of the oil pressure measuring units 320 increases, the ejection uniformity can be measured with more precise resolution. The smaller the distance between the oil pressure measuring units 320, the more preferable. Such an oil pressure measuring unit 320 may include every kind of sensor which can measure ejection pressure applied to the detection surface 320f, including a piezoelectric element.

That is, in order to measure the uniformity of photoresist PR using the apparatus for measuring ejection uniformity, the photoresist PR can be used as fluid Fl. In this case, however, since the photoresist PR to be used in the apparatus for measuring ejection uniformity is expensive and should be discarded, a lot of cost is required. Further, the photoresist PR has predetermined viscosity. Therefore, when the ejected photoresist PR remains on the detection surface 320f of the oil measuring unit 320, the oil measuring unit 320 cannot measure the ejection pressure of fluid Fl to be applied to the detection surface 320f with reliability. Therefore, as for fluid Fl to be used in the apparatus for measuring widthwise ejection uniformity, gas as well as liquid can be used. For example, water or air is preferably used. When ejection pressure of fluid Fl according to the widthwise direction of the slit nozzle 110 is measured for each interval, an absolute value and ejection behavior for each interval are not measured, but the distribution for each interval is relatively measured. Therefore, the photoresist PR or a material having the same physical property as the photoresist PR does not need to be used.

Hereinafter, a case will be described where water is used as the fluid Fl. A case where air is used as the fluid Fl will be again described afterwards.

When water is used as the fluid Fl, it is preferable that the ejection port 112 of the slit nozzle 110 and the detection surface 320f of the oil measuring unit 320 are spaced at less than a predetermined distance from each other. When the distance is large, the fluid Fl ejected from the ejection port 112 of the slit nozzle 110 is lumped into droplets due to a surface tension. Then, the fluid Fl ejected from the ejection port 112 may not be applied to the oil pressure measuring unit 320 positioned under the ejection port 112. Therefore, it is preferable that the distance between the ejection port 112 of the slit nozzle 110 and the detection surface 320f of the oil measuring unit 320 is set to less than 300 μm.

Meanwhile, after the ejection pressure of the fluid Fl applied to the oil measuring unit 320 is measured, the fluid Fl flows downward. The fluid Fl needs to be collected by a fluid collecting container (not shown) positioned under each of the oil pressure measuring units 320.

As described above, it is preferable that the fluid Fl to be ejected from the slit nozzle 110 does not remain on the detection surface 320f after being applied on the detection surface 320f of the oil pressure measuring unit 320. For this, it is preferable that the detection surface 320f of the oil pressure measuring unit 320 is formed to have a slightly larger width in the front and rear direction than the space of the ejection port 112, and an inclined surface 320i is formed between the detection surface 320 and the front and rear surfaces of the oil pressure measuring unit 320 (In FIG. 4, the front and rear direction is seen as the left and right direction). Then, the fluid Fl, such as water, ejected onto the detection surface 320f flows down along the inclined surface 320i so as not to remain on the detection surface 320f. In FIG. 4, the detection surface 320f and the inclined surface 320i forms an angle. Preferably, a corner between the detection surface 320f and the inclined surface 320i may be formed in a round shape. At this time, the ejection pressure is measured only by the detection surface 320f of the oil pressure measuring unit 320, but is not measured by the inclined surface 320i.

In order to make the fluid Fl flow down through the inclined surface 320i from the detection surface 320f, the oil pressure measuring unit 320 is surface-treated to have hydrophobicity such that the fluid Fl is not adhered on the surface of the oil pressure measuring unit 320. That is, the oil pressure measuring unit 320 is surface-treated so as not to be wetted by the fluid Fl. For example, hydrophobic coating can be performed on the surface of the oil pressure measuring unit 320, or surface roughness can be increased.

As shown in FIG. 3, the oil pressure measuring unit 320 disposed to correspond to either end of the slit nozzle 110 is spaced at a predetermined distance Lm from the end of the slit nozzle 110. This is because, when photoresist PR is coated on a substrate by the slit nozzle 110, the thickness uniformity of the photoresist PR to be coated from the widthwise edge of the slit nozzle 110 is not considered to be important. Therefore, the distance Lm corresponds to the width of a region where the thickness uniformity of the coated photoresist PR is not important. In some cases, however, when an distributed amount of photoresist PR in this region needs to be measured, the oil pressure measuring unit 320 can be also disposed in the region.

The apparatus for measuring widthwise ejection uniformity according to the invention serves to measure widthwise ejection uniformty of photoresist PR to be ejected from a slit coater which coats such a material as photoresist PR on a glass substrate at a predetermined thickness. For this, the apparatus for measuring ejection uniformity is disposed under the slit nozzle 110 which acutally ejects photoresist PR. Then, instead of photoresist PR, water is ejected as the fluid Fl such that the distribution of photoresist PR according to the widthwise direction of the slit nozzle 110 is measured.

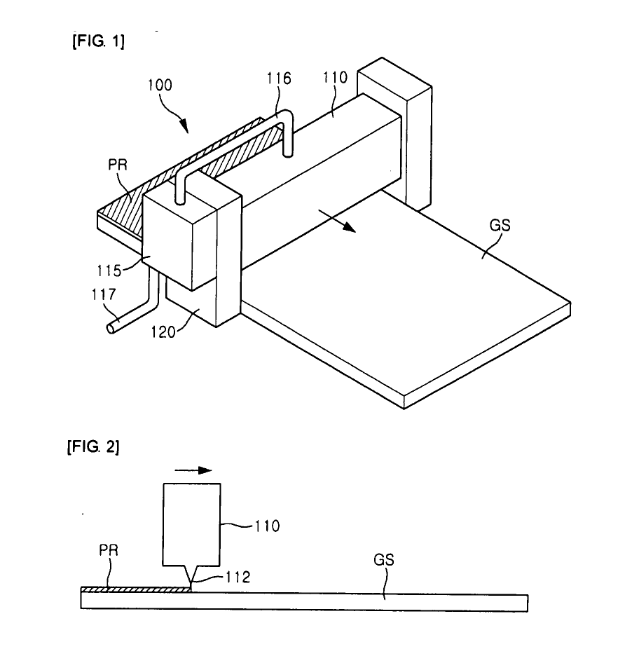

In order to measure the distribution of ejected fluid Fl according to the widthwise direction of the slit nozzle 110 using the apparatus for measuring widthwise ejection uniformity, the apparatus is disposed under the slit nozzle 110, as shown in FIGS. 3 and 4. After that, water, not photoresist PR, is supplied to the photoresist supply section 115 through the second photoresist supply line 117 of the slit coater (refer to FIG. 1) described in the related art. Next, the pump of the photoresist supply section 115 is driven so as to supply the water to the slit nozzle 110 through the first photoresist supply line 116. Then, the water is ejected onto the detection surface 320f of the oil pressure measuring unit 320 through the ejection port 112 of the slit nozzle 110. Typically, an amount of photoresist PR to be ejected by the slit nozzle 110 is about 0.5 to 15.0 cc/sec in an actual coating process, which is determined by the size of a substrate and the transfer speed of the slit nozzle 110. Therefore, an amount of water to be ejected onto the detection surface 320f of the oil measuring unit 320 is set to about 1.0 to 12.0 cc/sec.

Under the ejection port 112 of the slit nozzle 110, the plurality of oil pressure measuring units 320 having the detection surface 320f with a predetermined width are arranged in the widthwise direction of the slit nozzle 110. Therefore, the detection surface 320f of each of the oil pressure measuring units 320 receives only a constant amount of fluid Fl which is ejected from the ejection port 112 so as to correspond to the width of the detection surface 320f. Accordingly, each of the oil pressure measuring units 320 measures ejection pressure of fluid Fl which is ejected from the ejection port 112 so as to correspond to the width of the detection surface 320f.

That is, the ejection pressure of fluid Fl to be ejected from the ejection port 112 is uniformly measured for a predetermined width, and the signal is transmitted to the control unit 360. The control unit 360 calculates the ejection pressure of the fluid Fl, which has been measured by each of the oil pressure measuring units 320, so as to measure a change in ejection pressure according to the widthwise direction of the slit nozzle 110. The change in ejection pressure according to the widthwise direction of the slit nozzle 110 is represented by the uniformity of fluid Fl.

Preferably, the measuring of the uniformity of fluid Fl is repeatedly performed about ten times, in order to secure reliability. When the measuring is completed, the space of the ejection port 112 of the slit nozzle 110 is adjusted on the basis of the uniformity. The measuring of the uniformity of fluid and the adjusting of the space of the ejection port 112 are repeatedly performed until desirable uniformity of ejection liquid is obtained.

In the above-described embodiment, the plurality of oil pressure measuring units 320 are disposed at a predetermined distance under the ejection port 112 of the slit nozzle 110 such that the ejection pressure of fluid Fl is measured at the same time. However, the ejection pressure of fluid Fl may be measured using one oil pressure measuring unit, while the oil pressure measuring unit is transferred in the widthwise direction of the slit nozzle 110.

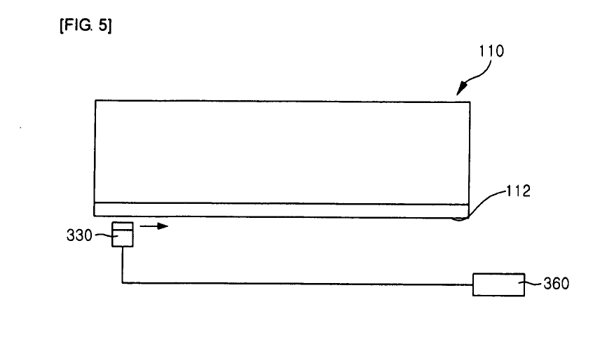

That is, an apparatus for measuring widthwise ejection uniformity shown in FIG. 5 includes an oil pressure measuring unit 330 which is positioned at a predetermined distance from the ejection port 112 as the lower end of the slit nozzle 110 and is installed so as to move in the widthwise direction of the slit nozzle 110; a transfer unit (not shown) which transfers the oil pressure measuring unit 330; and a control unit 360 which is connected to the oil pressure measuring unit 330 and controls the transfer unit. The control unit 360 receives a signal from the oil pressure measuring unit 330 so as to measure ejection pressure applied to the oil pressure measuring unit 330. Then, the control unit 360 calculates the uniformity of ejected fluid Fl to display.

Except that the oil pressure measuring unit 330 is movably installed, the oil pressure measuring unit 330 has the same construction as the oil pressure measuring unit 320. The transfer unit serves to transfer the oil pressure measuring unit 330 in the widthwise direction of the slit nozzle 110. As for the transfer unit, an oil or air pressure cylinder, a motor, a rack pinion machine or the like can be used. Since such an equipment is well-known in the this technical field, the descriptions thereof will be omitted.

The apparatus for measuring widthwise ejection uniformity, constructed in such a manner and shown in FIG. 5, transfers the oil pressure measuring unit 330 in the widthwise direction of the slit nozzle 110 at predetermined speed, while the slit nozzle 110 ejects fluid Fl. At the same time, the apparatus measures a change in ejection pressure, thereby obtaining a change in ejection pressure in accordance with time. At this time, if the time is multiplied by the speed of the oil pressure measuring unit 330, the movement distance of the oil pressure measuring unit 330 for the widthwise direction of the slit nozzle 110 is calculated. Therefore, the ejection pressure of fluid Fl with respect to the widthwise direction of the slit nozzle 110 is obtained, and a change in ejection pressure is represented as the uniformity of fluid Fl.

At this time, the transfer unit should be able to transfer the oil pressure measuring unit 330 at predetermined speed in the overall width region of the slit nozzle 110 (or in a region excluding at least a predetermined portion (corresponding to the distance Lm) in either end of the slit nozzle 110). For this, considering the acceleration and deceleration of the oil pressure measuring unit 330 when the oil pressure measuring unit 330 is transferred firstly and lastly, it is preferable that the transfer unit starts to transfer the oil pressure measuring unit 330 from the outside of one end of the slit nozzle 110 and stops the oil pressure measuring unit 330 at the outside of the other end thereof. At this time, when the oil pressure measuring unit 330 passes by both ends of the slit nozzle 110, a trigger signal is applied with an oil-pressure change signal such that the positions of both ends of the slit nozzle 110 are displayed.

In the above-described embodiment, it has been described that water is used as fluid Fl. However, gas can be used as the fluid Fl. As for the fluid Fl, non-reacting gas such as air, nitrogen, or argon is preferably used. In this case, the non-reacting gas as the fluid Fl does not remain on the oil pressure measuring unit. Further, after the ejection pressure of the fluid Fl applied to the oil pressure measuring unit is measured, the fluid Fl does not need to be collected separately.

However, when non-reacting gas such as air is used as the fluid Fl, there are difficulties in using the first and second photoresist supply lines 116 and 117 and the photoresist supply section 15, shown in FIG. 1, as they are. For example, there is a limit in driving the pump provided in the photoresist supply section 115 so as to supply non-reacting gas to the slit nozzle 110. Therefore, a gas supply unit (not shown) should be further provided, which is connected to the slit nozzle 110 so as to supply non-reacting gas to the slit nozzle 110.

When non-reacting gas is used as fluid Fl, the construction and operation of the apparatus for measuring ejection uniformity according to the invention is the same as the case where water is used as fluid Fl, except that a gas supply unit for supplying non-reacting gas to the slit nozzle 110 is separately provided. Therefore, the descriptions thereof will be omitted.

According to the apparatus and method for measuring widthwise ejection uniformity of slit nozzle, the ejection uniformity of photoresist to be ejected on a substrate by the slit nozzle can be simply and precisely measured in the widthwise direction of the slit nozzle.

Through the measuring, the space of the ejection port of the slit nozzle can be easily adjusted. Therefore, a preparation time required for coating a substrate by using a slit coater and the resultant overall process time can be reduced.

Further, since photoresist does not need to be used but water or non-reacting gas is used for measuring widthwise ejection uniformity of photoresist, expensive photoresist is not wasted. Accordingly, it is possible to reduce a disposal cost of photoresist to be discarded.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An apparatus for measuring withwise ejection uniformity of a slit nozzle, the apparatus comprising:
a plurality of oil pressure measuring units that are arranged in parallel in a widthwise direction of the slit nozzle so as to measure ejection pressure of fluid to be ejected from an ejection port of the slit nozzle, each oil pressure measuring unit having an oil-pressure detection surface facing the ejection port of the slit nozzle; and
a control unit that measures ejection pressure applied to the oil pressure measuring unit so as to calculate the uniformity to display.

2. An apparatus for measuring ejection uniformity of a slit nozzle, the apparatus comprising:
an oil pressure measuring unit that is disposed in a widthwise direction of the slit nozzle so as to measure ejection pressure of fluid to be ejected from an ejection port of the slit nozzle, the oil pressure measuring unit having an oil-pressure detection surface facing the ejection port of the slit nozzle;
a control unit that measures ejection pressure applied to the oil pressure measuring unit so as to calculate the uniformity to display; and
a transfer unit that transfers the oil pressure measuring unit in the widthwise direction of the slit nozzle.

3. The apparatus according to claim 1,
wherein the slit nozzle ejects water or gas.

4. The apparatus according to claim 1,
wherein the oil pressure measuring unit is surface-treated so as to have hydrophobicity with respect to ejected fluid.

5. The apparatus according to claim 1,
wherein the oil pressure measuring unit has an inclined surface formed between the detection surface and the front and rear surfaces thereof.

6. The apparatus according to claim 5,
wherein the corner between the detection surface and the inclined surface is formed in a round shape.

7. The apparatus according to claim 1,
wherein the oil pressure measuring unit includes a piezoelectric element.

8. A method for measuring widthwise ejection uniformity of a slit nozzle, the method comprising:
ejecting fluid through an ejection port of the slit nozzle;
measuring ejection pressure of the fluid to be ejected in the widthwise direction of the slit nozzle; and
calculating ejection uniformity based on the measured ejection pressure and displaying the ejection uniformity.

9. The method according to claim 8,
wherein the measuring of the ejection pressure of the fluid includes arranging a plurality of oil pressure measuring units in the widthwise direction of the slit nozzle so as to measure the ejection pressure at the same time.

10. The method according to claim 8,
wherein the measuring of the ejection pressure of the fluid includes measuring the ejection pressure while transferring one oil pressure measuring unit in the widthwise direction of the slit nozzle.
